(19) United States
(12) Patent Application Publication
(10) Pub. No.: US 2014/0185200 A1
(43) Pub. Date: Jul. 3, 2014

(54) DISPLAY APPARATUS

(71) Applicant: FUNAI ELECTRIC CO., LTD., Osaka (JP)

(72) Inventors: Yasuhiro MORI, Osaka (JP); Masayoshi KOBAYASHI, Osaka (JP); Akira YOKAWA, Osaka (JP); Akihiro FUJIKAWA, Osaka (JP)

(73) Assignee: FUNAI ELECTRIC CO., LTD., Osaka (JP)

(21) Appl. No.: 14/102,620

(22) Filed: Dec. 11, 2013

(30) Foreign Application Priority Data
Dec. 27, 2012 (JP) 2012-285878

(51) Int. Cl. H05K 7/02

(52) U.S. Cl. CPC H05K 7/02
USPC 361/679.01

(57) ABSTRACT

A display apparatus including: a liquid-crystal panel; a rear frame which includes an opening portion and is provided on a rear side of the liquid-crystal panel; a back light which is provided between the liquid-crystal panel and the rear frame and emits light toward a rear face of the liquid-crystal panel; a cell guide which is provided corresponding to a predetermined rim portion of the opening portion and supports at least part of an outer-circumferential portion of the liquid-crystal panel from the rear side; a joining portion which is provided on a portion of the rear frame which corresponds to the predetermined rim portion, and extends toward the liquid-crystal panel to join the cell guide to the rear frame; and a screw which fastens the cell guide and the joining portion together, wherein the screw is tightened from a lateral side of the display apparatus.

### CROSS REFERENCE TO RELATED APPLICATION

The present application is based on and claims priority of Japanese Patent Application No. 2012-285878 filed on Dec. 27, 2012. The entire disclosure of the above-identified application, including the specification, drawings and claims is incorporated herein by reference in its entirety.

### FIELD

The present invention relates to display apparatuses for displaying images.

### BACKGROUND

There have conventionally been display devices, such as liquid-crystal television receivers and so on, which include back lights that emit light toward the rear face of a display panel (see Patent Literature (PTL) 1, for example).

A housing of such a display device includes a resin-made front cabinet on the display panel side and a metallic rear frame on the back light side. The rear frame is provided with a rectangular opening portion for placing the display panel. To four rim portions of the opening portion of the rear frame, hold plates extending along the respective rim portions are joined with screws or the like. These four hold plates are placed so as to form a frame shape as a whole. On these four hold plates, an outer-circumferential portion of the display panel is supported with a cell guide therebetween. Furthermore, the outer-circumferential portion of the display panel on the front side is covered by a bezel. As a result, the outer-circumferential portion of the display panel is held between the bezel and the cell guide. With the bezel and the cell guide each fixed to the four hold plates with screws or the like, the display panel is placed in the opening portion of the rear frame in a fixed manner.

### CITATION LIST

### Patent Literature

[PTL 1] Japanese Unexamined Patent Application Publication No. H5-103284

### SUMMARY

### Technical Problem

As described above, the conventional display device uses the four hold plates as components for placing the display panel in the opening portion of the rear frame in a fixed manner. Thus, the number of components in the display device is large, which causes a problem that the display apparatus has a complicated structure.

The present invention is devised to solve the above problem and aims to provide a display apparatus in which the number of components for placing a display panel in an opening portion of a rear frame in a fixed manner can be reduced.

### Solution to Problem

In order to achieve the above object, a display apparatus according to an aspect of the present invention is a display apparatus for displaying an image, comprising: a display panel which displays the image; a rear frame which includes an opening portion and is provided on a rear side of the display panel; a back light which is provided between the display panel and the rear frame and emits light toward a rear face of the display panel; a supporting member which is provided corresponding to a predetermined rim portion of the opening portion and supports at least part of an outer-circumferential portion of the display panel from the rear side; a joining portion which is provided on a portion of the rear frame and extends toward the display panel to join the supporting member to the rear frame, the portion of the rear frame corresponding to the predetermined rim portion; and a fastening member which fastens the supporting member and the joining portion together, wherein the fastening member is tightened from a lateral side of the display apparatus.

According to this aspect, providing the rear frame with the joining portion for joining the support member allows to omit, for example, such four hold plates as described in the Background section. Thus, it is possible to reduce the number of components for placing the display panel in the opening portion of the rear frame in a fixed manner. Furthermore, the fastening member is tightened from a lateral side of the display apparatus, with the result that the front end of the fastening member will not be seen as an appearance of the display apparatus, which can lead to enhanced design, and the dimension of the supporting member in the depth direction can be small.

For example, the display apparatus according to an aspect of the present invention may have a configuration such that the fastening member extends in a direction which is substantially parallel to the display panel and substantially perpendicular to the predetermined rim portion.

According to this aspect, the fastening member extends in a direction which is substantially parallel to the display panel and substantially perpendicular to the rim portion, with the result that the front end of the fastening member will not be seen as an appearance of the display apparatus, which can lead to enhanced design, and the dimension of the supporting member in the width direction can be small.

For example, the display apparatus according to an aspect of the present invention may have a configuration such that the joining portion is provided at a position more inward on the rear frame than the predetermined rim portion.

According to this aspect, the joining portion is provided at a position more inward on the rear frame than the predetermined rim portion, with the result that one end portion of the fastening member (e.g., a head portion or the like of a screw) can be housed at a position more inward on the rear frame than the predetermined rim portion.

For example, the display apparatus according to an aspect of the present invention may have a configuration such that a connecting portion which connects the predetermined rim portion and the joining portion to each other is further included, and the supporting member is supported by the connecting portion.

According to this aspect, the supporting member is supported by the connecting portion, with the result that the supporting member can be stably supported with respect to the rear frame.

For example, the display apparatus according to an aspect of the present invention may have a configuration such that the supporting member is provided with one of a protruding portion and a depressed portion, the joining portion is provided with the other of the protruding portion and the depressed portion, and the supporting member is positioned with respect to the rear frame through insertion of the protruding portion into the depressed portion.

According to this aspect, the insertion of the protruding portion into the depressed portion allows the supporting member to be easily positioned with respect to the rear frame.

For example, the display apparatus according to an aspect of the present invention may have a configuration such that the fastening member is a screw, and the other of the protruding portion and the depressed portion of the joining portion is located to the left of the screw as viewed in a motion direction of the screw which is being rotated in a tightening direction.

According to this aspect, the relationship of relative positions of the screw and the protruding or depressed portion is set as above, with the result that the screw and the supporting member can be prevented from rotating in coordination when the screw is being tightened, so that the supporting member does not float above from the rear frame.

### Advantageous Effects

According to the present invention, it is possible to reduce the number of components for placing the display panel in the opening portion of the rear frame in a fixed manner.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 is a perspective view showing, from the front side, a display apparatus according to Embodiment 1 of the present invention.

FIG. 2 is a perspective view showing the display apparatus of FIG. 1 from the rear side.

FIG. 3 is a plan view showing the interior of the display apparatus of FIG. 1.

FIG. 4 is a perspective view showing a magnified version of a predetermined rim portion of an opening portion of a rear frame.

FIG. 5 is a main-part perspective view showing, with the rear frame, a bezel and a cell guide each detached from the rear frame.

FIG. 6 is a main-part sectional view of the display apparatus taken along line A-A in FIG. 4.

FIG. 7 is a main-part sectional view of the display apparatus taken along line B-B in FIG. 4.

FIG. 8 is a main-part sectional view showing a display apparatus according to Embodiment 2 of the present invention.

### DESCRIPTION OF EMBODIMENTS

Embodiments of the present invention will be described in detail below with reference to the drawings. It is to be noted that each of the embodiments described below indicates a preferred specific example of the present invention. The numerical values, shapes, materials, structural elements, the arrangement and connection of the structural elements, steps, the order of the steps etc. shown in the following embodiments are examples, and therefore do not intend to limit the present invention. The present invention is defined by the Claims. Therefore, among the structural elements in the following embodiments, structural elements not recited in any one of the independent claims are not necessarily required to achieve the objective of the present invention, but are described as elements which are included in more preferred embodiments.

### Embodiment 1

### [Configuration of Display Apparatus]

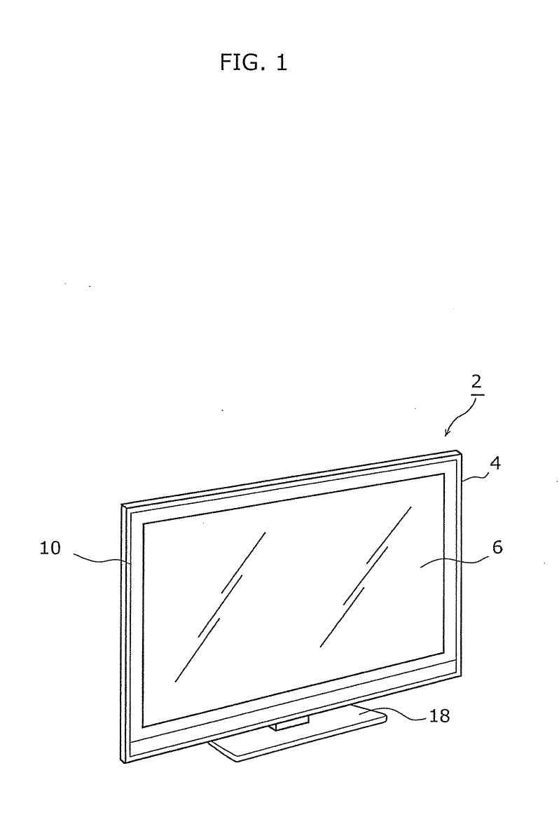

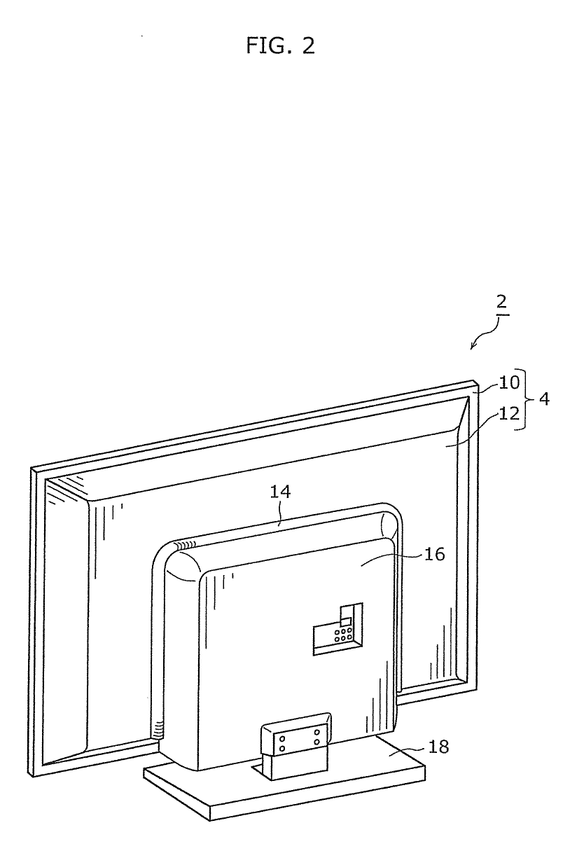

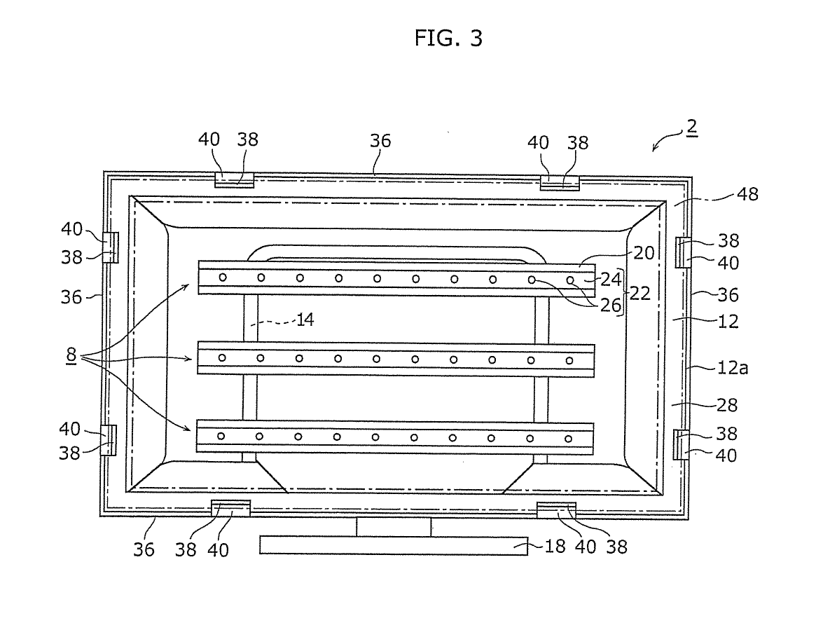

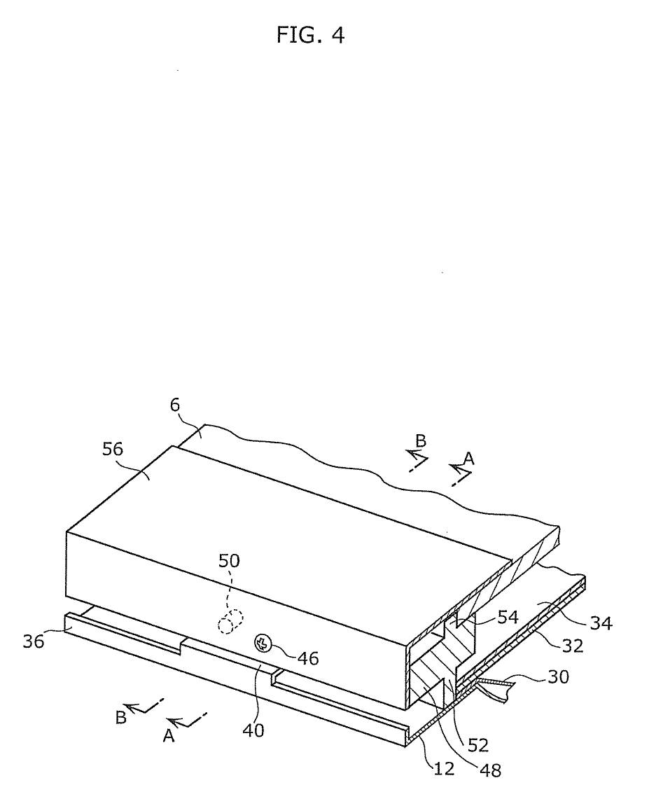

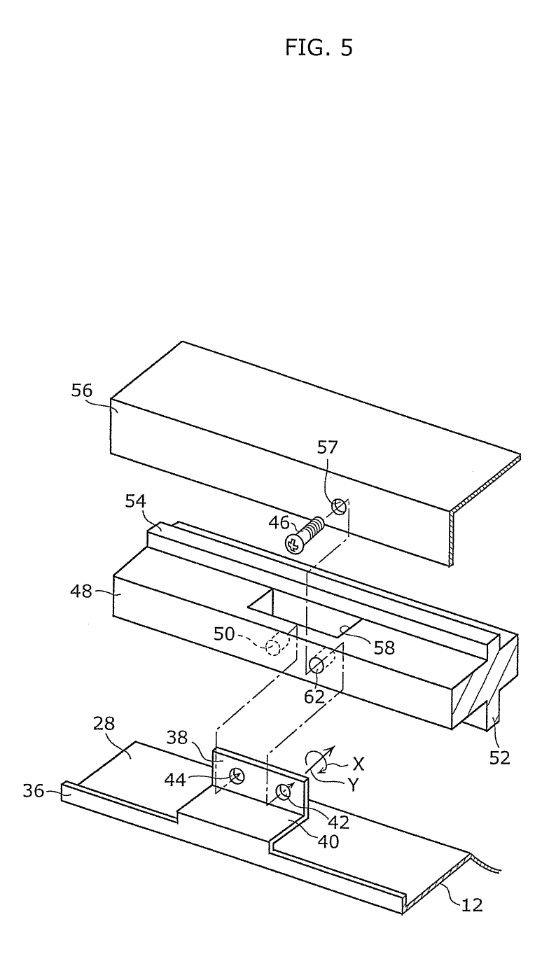

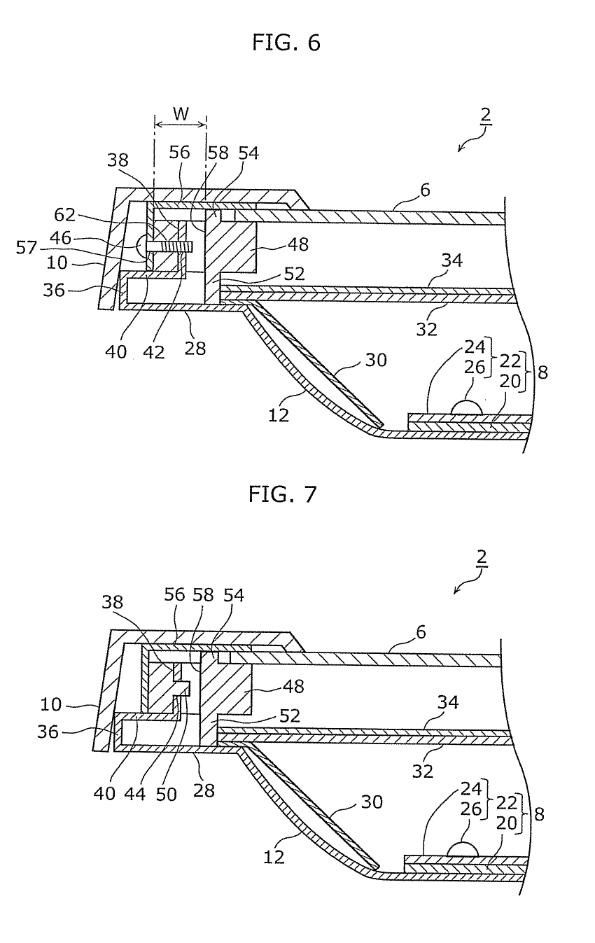

Firstly, a display apparatus according to Embodiment 1 of the present invention is described with reference to FIG. 1 to FIG. 7. FIG. 1 is a perspective view showing, from the front side, a display apparatus according to Embodiment 1 of the present invention. FIG. 2 is a perspective view showing the display apparatus of FIG. 1 from the rear side. FIG. 3 is a plan view showing the interior of the display apparatus of FIG. 1. FIG. 4 is a perspective view showing a magnified version of a predetermined rim portion of an opening portion of a rear frame. FIG. 5 is a main-part perspective view showing, with the rear frame, a bezel and a cell guide each detached from the rear frame. FIG. 6 is a main-part sectional view of the display apparatus taken along line A-A in FIG. 4. FIG. 7 is a main-part sectional view of the display apparatus taken along line B-B in FIG. 4.

A display apparatus 2 shown in the drawings includes a housing 4, and a liquid-crystal panel 6 (which constitutes a display panel) and a plurality of back lights 8, both of which are provided inside the housing 4. The display apparatus 2 in this embodiment is a liquid-crystal television receiver which adopts the direct-backlit system and includes the back lights 8.

The housing 4 includes a front cabinet 10 and a rear frame 12 which are combined with each other.

The front cabinet 10 is provided on the front side of the liquid-crystal panel 6. The front cabinet 10 is formed into a frame shape and covers an outer-circumferential portion of the liquid-crystal panel 6. It is to be noted that the front cabinet 10 is formed of resin or the like, for example.

The rear frame 12 is provided so as to cover the whole rear face of the liquid-crystal panel 6. The rear frame 12 is slightly swollen in shape in the opposite direction from the liquid-crystal panel 6 and includes a rectangular opening portion 12a for placing the liquid-crystal panel 6. In a central area on the outer face of the rear frame 12 (which is a face opposite from the liquid-crystal panel 6), a power source substrate (not shown) or the like for supplying electric power to the liquid-crystal panel 6, the back lights 8, and the like is mounted. It is to be noted that the rear frame 12 is formed of a metal having high heat conductivity, such as aluminum, for example.

To the outer face of the rear frame 12, a rear cover 16 is joined. The above-stated power source substrate or the like is covered by this rear cover 16. The rear frame 12 includes a protruding portion 14 for positioning the rear cover 16 with respect to the rear frame 12. This protruding portion 14 extends along an outer-circumferential portion of the rear cover 16 and protrudes in the opposite direction from the liquid-crystal panel 6. When the outer-circumferential portion of the rear cover 16 comes into contact with an inner-circumferential portion of the protruding portion 14, the rear cover 16 is positioned with respect to the rear frame 12. To a lower end portion of the rear cover 16, a stand 18 for supporting the housing 4 from below is joined. It is to be noted that the rear cover 16 is formed of resin or the like, for example.

Each of the back lights 8 extends linearly in the lateral direction and is supported on an inner face of the rear frame 12 as shown in FIG. 3 so as to allow heat conduction. The back lights 8 are arranged substantially parallel to each other. When supplied with electric power from the above-stated power source substrate, each of the back lights 8 emits light toward the rear face of the liquid-crystal panel 6.

Each of the back lights 8 includes a heat sink 20 and a light emitting diode (LED) bar 22 joined to the heat sink 20. The heat sink 20 has an elongated plate shape and is fastened to the inner face of the rear frame 12 with a plurality of screws (not shown). The LED bar 22 includes a wiring substrate 24 and a plurality of LEDs 26 mounted on the wiring substrate 24. The wiring substrate 24 has an elongated plate shape. The LEDs 26 are arranged at intervals in line along the longitudinal direction of the wiring substrate 24. The wiring substrate 24 is joined to the heat sink 20 with a double sided tape (not shown) having heat conductivity. Each of the heat sink 20 and the wiring substrate 24 is formed of a metal having high heat conductivity, such as aluminum, for example.

The following describes a feature of the display apparatus 2 in this embodiment, that is, the configuration for placing the liquid-crystal panel 6 in the opening portion 12a of the rear frame 12 in a fixed manner.

As shown in FIG. 3 to FIG. 7, the rear frame 12 includes a flange portion 28 on an outer-circumferential portion of the opening portion 12a. This flange portion 28 extends outward on the rear frame 12 and substantially parallel to the liquid-crystal panel 6.

This flange portion 28 supports each outer-circumferential portion of a reflection sheet 30, a diffuser plate 32, and a prism sheet 34. The reflection sheet 30 is located around the back lights 8 and has a function of reflecting light from each of the back lights 8. The diffuser plate 32 is located between the back lights 8 and the liquid-crystal panel 6 and has a function of diffusing light from the back lights 8. The prism sheet 34 is provided so as to cover a liquid-crystal panel 6-side face of the diffuser plate 32 and has a function of guiding, to the rear face of the liquid-crystal panel 6, the light diffused by the diffuser plate 32.

Four rim portions (edges) 36 of the opening portion 12a of the rear frame 12 stand from the outer-circumferential portion of the flange portion 28 substantially perpendicularly toward the liquid-crystal panel 6. A pair of joining portions 38 is provided on a portion of the rear frame 12 which corresponds to each of the four rim portions 36. Each pair of the joining portions 38 and the predetermined rim portion 36 which corresponds to the pair are connected to each other through a connecting portion 40. The connecting portion 40 extends inward on the rear frame 12 from the rim portion 36 and substantially parallel to the liquid-crystal panel 6. The joining portion 38 extends from one end portion of the connecting portion 40 toward the liquid-crystal panel 6 and substantially perpendicularly to the liquid-crystal panel 6. In other words, the joining portion 38 is provided at a position more inward on the rear frame 12 than the predetermined rim portion 36. It is to be noted that the joining portion 38, the connecting portion 40, and the rear frame 12 are integrally formed into a sheet metal, for example.

As shown in FIG. 5, the joining portion 38 includes a screw hole 42 and a protrusion through hole 44 (which constitutes a depressed portion). The screw hole 42 is a hole in which a screw 46 (which constitutes a fastening member) is tightened. It is to be noted that the screw 46 is a round screw or the like in this embodiment. The protrusion through hole 44 is a hole into which a protrusion 50 (described hereinafter) provided on a cell guide 48 (described hereinafter) is inserted. The protrusion through hole 44 is located to the left of the screw hole 42 as viewed in the motion direction (the direction indicated by an arrow Y in FIG. 5) of the screw 46 which is being rotated in the tightening direction (the direction indicated by an arrow X in FIG. 5).

As shown in FIG. 3, the cell guide 48 (which constitutes a supporting member) is provided for each of the four rim portions 36 of the opening portion 12a of the rear frame 12 and supports an outer-circumferential portion of the liquid-crystal panel 6 from the rear side of the liquid-crystal panel 6. The cell guide 48 has a frame shape, for example.

As shown in FIGS. 4 to 7, a first rib 52 is provided on the rear frame 12-side face of the cell guide 48 and a second rib 54 is provided on the liquid-crystal panel 6-side face of the cell guide 48. The first rib 52 protrudes toward the rear frame 12, and the second rib 54 protrudes toward the liquid-crystal panel 6. The first rib 52 is provided on the outer side of the outermost profile of each of the reflection sheet 30, the diffuser plate 32, and the prism sheet 34 supported by the flange portion 28, in a manner that forms, between the cell guide 48 and the flange portion 28, a space for a total thickness of the reflection sheet 30, the diffuser plate 32, and the prism sheet 34. The second rib 54 is provided in a manner that forms, between the cell guide 48 and a bezel 56 (described hereinafter), a space for the thickness of the liquid-crystal panel 6.

A joining depressed portion 58 is provided in a portion of the cell guide 48 which corresponds to each of the joining portions 38. This joining depressed portion 58 extends in the direction substantially perpendicular to the liquid-crystal panel 6 and penetrates the cell guide 48. On an inner-circumferential face of the joining depressed portion 58, a protrusion 50 (which constitutes a protruding portion) is provided which protrudes inward in the radial direction of the joining depressed portion 58. Furthermore, in a portion of the cell guide 48 which is on the outer side of the joining depressed portion 58, a screw through hole 62 into which the screw 46 is inserted is provided. The joining portion 38 is inserted into this joining depressed portion 58, and the portion of the cell guide 48 which is on the outer side of the joining depressed portion 58 is supported by the connecting portion 40. As shown in FIG. 6, the screw 46 is inserted into the screw through hole 62 and tighten in the screw hole 42 to fasten the cell guide 48 and the joining portion 38 together so that the cell guide 48 is joined to the rear frame 12. The screw 46 is tightened from a lateral side of the display apparatus 2. In other words, the screw 46 extends in the direction which is substantially parallel to the liquid-crystal panel 6 and substantially perpendicular to the rim portion 36. Furthermore, as shown in FIG. 7, the protrusion 50 is inserted into the protrusion through hole 44, thereby positioning the cell guide 48 with respect to the rear frame 12.

As described above, the protrusion through hole 44 is located to the left of the screw hole 42 as viewed in the motion direction of the screw 46 which is being rotated in the tightening direction. With this, the screw 46 and the cell guide 48 can be prevented from rotating in coordination when the screw 46 is being tightened in the screw hole 42, so that the cell guide 48 does not float above from the connecting portion 40. Furthermore, with the portion of the cell guide 48 outside the joining depressed portion 58 supported by the connecting portion 40, the cell guide 48 can be stably supported with respect to the rear frame 12.

The liquid-crystal panel 6 has a rectangular shape and is supported by an inner-circumferential portion of the cell guide 48 (that is, a portion of the cell guide 48 which is more inward than the second rib 54). When the rear face of the liquid-crystal panel 6 is irradiated with light from the back lights 8, the liquid-crystal panel 6 displays images. The outer-circumferential portion of the liquid-crystal panel 6 on the front side is covered by the bezel 56. The bezel 56 has a frame shape, for example, and includes, on a predetermined portion of the bezel 56, a screw through hole 57 into which the screw 46 is inserted. As shown in FIG. 6, the screw 46 is inserted into the screw through holes 57 and 62 and tightened in the screw hole 42 to fasten the bezel 56 to the cell guide 48 and the rear frame 12. With this, the outer-circumferential portion of the liquid-crystal panel 6 is held between the bezel 56 and the cell guide 48. As described above, the liquid-crystal panel 6 is placed in the opening portion 12a of the rear frame 12 in a fixed manner.

It is to be noted that the front cabinet 10 is joined to the rear frame 12 with a plurality of screws (not shown) so as to cover the bezel 56 and the cell guide 48. In addition, as described above, the joining portion 38 is provided at a position more inward on the rear frame 12 than the rim portion 36, with the result that a head portion of the screw 46 can be housed at a position more inward on the rear frame 12 than the rim portion 36. With this, the head portion of the screw 46 will not come into contact with an inner face of the front cabinet 10 so that the frame of the front cabinet 10 can be reduced in width.

### [Effect]

Next, an effect obtained by the display apparatus 2 in this embodiment is described. As described above, the rear frame 12 is provided with the joining portion 38 for joining the cell guide 48, with the result that such four hold plates, for example, as described in the Background section can be omitted. This makes it possible to reduce the number of components for placing the liquid-crystal panel 6 in the opening portion 12a of the rear frame 12 in a fixed manner.

Furthermore, as described above, the screw 46 extends in the direction which is substantially parallel to the liquid-crystal panel 6 and substantially perpendicular to the rim portion 36. With this, the front end of the screw 46 will not be seen as an appearance of the display apparatus 2, which can lead to enhanced design.

If the screw 46 extends in the direction substantially perpendicular to the liquid-crystal panel 6, the dimension of the cell guide 48 in the width direction will increase by the proportion required to tighten the screw 46. In contrast, when the screw 46 extends in the direction which is substantially parallel to the liquid-crystal panel 6 and substantially perpendicular to the rim portion 36 as in this embodiment, it is sufficient that the dimension W of the cell guide 48 in the width direction (specifically, the dimension W of the portion of the cell guide 48 which is more outward than the second rib 54) corresponds to at least the length of the screw 46. Therefore, it is possible to reduce the dimension W of the cell guide 48 in the width direction by shortening the length of the screw 46. By doing so, the frame of the front cabinet 10 can be reduced in width in the display apparatus 2 in this embodiment.

### Embodiment 2

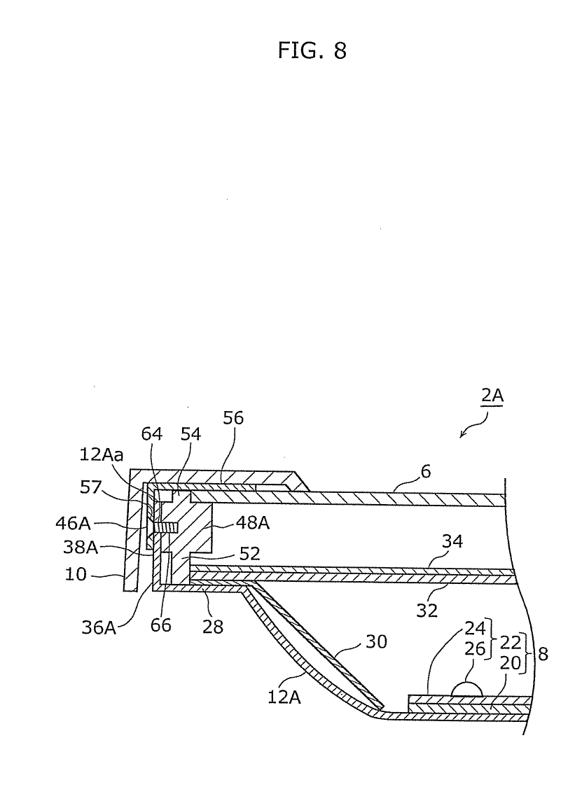

Next, a configuration of a display apparatus according to Embodiment 2 of the present invention is described with reference to FIG. 8. FIG. 8 is a main-part sectional view showing the display apparatus according to Embodiment 2 of the present invention.

In a display apparatus 2A in this embodiment, a joining portion 38A extends from a rim portion 36A of an opening portion 12Aa of a rear frame 12A toward the liquid-crystal panel 6. This means that the rear frame 12A is not provided with the connecting portion 40 described in the above Embodiment 1. The joining portion 38A is provided with a screw through hole 64 into which a screw 46A is inserted and a protrusion through hole (which constitutes a depressed portion) (not shown) into which a protrusion (described hereinafter) on a cell guide 48A is inserted. It is to be noted that the screw 46A is a countersunk head screw in this embodiment.

The cell guide 48A is not provided with the joining depressed portion 58 described in the above Embodiment 1. The cell guide 48A includes, in its outer-circumferential face, a screw hole 66 in which the screw 46A is tightened and a protrusion (which constitutes a protruding portion) (not shown) which protrudes outward in the radial direction of the cell guide 48A.

The screw 46A is inserted into the screw through holes 57 and 64 and tightened in the screw hole 66 to join the cell guide 48A to an inner face of the joining portion 38A. Furthermore, with the protrusion inserted into the protrusion through hole, the cell guide 48A is positioned with respect to the rear frame 12A.

Consequently, also with the display apparatus 2A in this embodiment, it is possible to obtain the same or the like effects as those in the above Embodiment 1. It is to be noted that the screw 46A may be a round screw or the like as in the case of the above Embodiment 1.

Although the display apparatuses according to Embodiments 1 and 2 of the present invention have been described above, the present invention is not limited to these embodiments. For example, the above embodiments may be combined.

Although the above has described the embodiments where the display apparatus is a liquid-crystal television receiver, the display apparatus may be other than the liquid-crystal television receiver, and may also be, for example, a liquid-crystal monitor for a personal computer, and the like.

Although the above embodiments adopt the back lights of the direct-backlit system, back lights of the edge-lit system may also be adopted.

Although the LED is used as an illuminant for the back light in the above embodiments, a cold cathode fluorescent lamp (CCFL) or the like can be used, for example.

Although the fastening member is a screw in the above embodiments, the fastening member may be other than the screw, and may also be, for example, a rivet, a fixing pin, and the like.

Although the joining portion includes a protrusion through hole as a depressed portion and the cell guide includes a protrusion as a protruding portion in the above embodiments, the opposite case is also possible; it may be that the cell guide includes a protrusion through hole as a depressed portion and the joining portion includes a protrusion as a protruding portion.

Although the cell guide has a frame shape in the above embodiments, the cell guide may be provided for each of the four rim portions of the opening portion. In this case, each of the four cell guides extends along the corresponding rim portion of the opening portion and supports part of the outer-circumferential portion of the liquid-crystal panel from the rear side thereof.

Although the joining portion is provided for each of the four rim portions of the opening portion in the above embodiments, the joining portion may be provided for at least a predetermined rim portion out of the four rim portions of the opening portion.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

### INDUSTRIAL APPLICABILITY

The display apparatus in the present invention is applicable, for example, as a liquid-crystal television receiver, a liquid-crystal monitor for a personal computer, and the like.

1. A display apparatus for displaying an image, comprising:
a display panel which displays the image;
a rear frame which includes an opening portion and is provided on a rear side of the display panel;
a back light which is provided between the display panel and the rear frame and emits light toward a rear face of the display panel;
a supporting member which is provided corresponding to a predetermined rim portion of the opening portion and supports at least part of an outer-circumferential portion of the display panel from the rear side;
a joining portion which is provided on a portion of the rear frame and extends toward the display panel to join the supporting member to the rear frame, the portion of the rear frame corresponding to the predetermined rim portion; and
a fastening member which fastens the supporting member and the joining portion together,
wherein the fastening member is tightened from a lateral side of the display apparatus.

2. The display apparatus according to claim 1,
wherein the fastening member extends in a direction which is substantially parallel to the display panel and substantially perpendicular to the predetermined rim portion.

3. The display apparatus according to claim 1,
wherein the joining portion is provided at a position more inward on the rear frame than the predetermined rim portion.

4. The display apparatus according to claim 3, further comprising
a connecting portion which connects the predetermined rim portion and the joining portion to each other,
wherein the supporting member is supported by the connecting portion.

5. The display apparatus according to claim 1,
wherein the supporting member is provided with one of a protruding portion and a depressed portion,
the joining portion is provided with the other of the protruding portion and the depressed portion, and
the supporting member is positioned with respect to the rear frame through insertion of the protruding portion into the depressed portion.

6. The display apparatus according to claim 5,
wherein the fastening member is a screw, and
the other of the protruding portion and the depressed portion of the joining portion is located to the left of the screw as viewed in a motion direction of the screw which is being rotated in a tightening direction.
